(19) United States
(12) Patent Application Publication
(10) Pub. No.: US 2017/0069271 A1
(43) Pub. Date: Mar. 9, 2017

(54) DISPLAY APPARATUS

(71) Applicant: SAMSUNG DISPLAY CO., LTD., Yongin-si (KR)

(72) Inventors: Kyung-Hoon Kim, Uiwang-si (KR); Seon-Young Choi, Gunpo-si (KR); Il-Gon Kim, Seoul (KR); Kang-Moon Jo, Hwaseong-si (KR); Gyung-Soon Park, Seoul (KR); Min-Jae Jeong, Suwon-si (KR)

(21) Appl. No.: 15/234,862

(22) Filed: Aug. 11, 2016

(30) Foreign Application Priority Data
Sep. 3, 2015 (KR) 10-2015-0124573

(51) Int. Cl. G09G 3/3258; G09G 3/3266; H01L 27/12; G09G 3/3275

(52) U.S. Cl. CPC G09G 3/3258; G09G 3/3275; G09G 3/3266; H01L 27/124; G09G 2310/0297; G09G 2300/0876; G09G 2320/0219; H01L 27/3262

(57) ABSTRACT

A display apparatus includes: a first gate line extending in a second direction crossing a first direction; a row line extending in the first direction and electrically connected to the first gate line; a first data line spaced from the first gate line along the first direction and extending in the second direction; a second data line adjacent to the first data line and extending in the second direction; a first sub-pixel electrically connected to the first data line; and a second sub-pixel electrically connected to the second data line.

### CROSS-REFERENCE TO RELATED APPLICATION

This application claims priority to and the benefit of Korean Patent Application No. 10-2015-0124573, filed on Sep. 3, 2015, the disclosure of which is incorporated by reference herein in its entirety.

### BACKGROUND

### 1. Field

One or more aspects of example embodiments of the present invention relate to a display apparatus. More particularly, one or more aspects of example embodiments of the inventive concept relate to an organic light emitting display apparatus.

### 2. Description of the Related Art

An organic light emitting display device may include a plurality of pixels, a data driver for transferring data signals to data lines, and a gate driver for transferring gate signals to gate lines. In general, the data driver may be located at an upper-side or a lower-side of a display panel, and the gate driver may be located at a left-side and/or a right-side of the display panel. The data driver may be connected to the plurality of pixels through the data lines that extend in a column direction, and the gate driver may be connected to the plurality of pixels through the gate lines that extend in a row direction.

The above information disclosed in this Background section is for enhancement of understanding of the background of the invention, and therefore, it may contain information that does not constitute prior art.

### SUMMARY

A display apparatus including the gate driver located at a side at which the data driver is located reduces dead space of the display panel. However, a number of signal lines extending in a direction that is the same as that of the data lines may be increased when the data driver and the gate driver are located at the same side, so that coupling capacitance caused between the data lines and/or between the data lines and the signal lines may degrade a display quality of the display apparatus.

One or more aspects of example embodiments of the present invention provide a display apparatus capable of improving display quality.

According to an example embodiment of the present invention, a display apparatus includes: a first gate line extending in a second direction crossing a first direction; a row line extending in the first direction and electrically connected to the first gate line; a first data line spaced from the first gate line along the first direction and extending in the second direction; a second data line adjacent to the first data line and extending in the second direction; a first sub-pixel electrically connected to the first data line; and a second sub-pixel electrically connected to the second data line.

In an embodiment, the display apparatus may further include: a data driver configured to provide data signals to the first and second data lines; and a gate driver configured to provide a gate signal to the first gate line. The data driver and the gate driver may be located at a same side of the display apparatus, or may be located at opposite sides of the display apparatus, respectively.

In an embodiment, the first sub-pixel may include a first driving transistor, and the second sub-pixel may include a second driving transistor, and the first data line and the second data line may be located between the first driving transistor and the second driving transistor.

In an embodiment, the display apparatus may further include a power voltage line extending in the second direction and configured to provide a first power voltage to the first and second sub-pixels, and the power voltage line may be located between the first gate line and the first and second data lines.

In an embodiment, the power voltage line may be connected to a conductive line extending in the first direction to form a mesh structure.

In an embodiment, the display apparatus may further include an initialization voltage line spaced from the power voltage line along the first direction and extending in the second direction.

In an embodiment, the initialization voltage line may be connected to a conductive line extending in the first direction to form a mesh structure.

In an embodiment, the data driver may include a demultiplexer configured to provide the data signals generated from a first data signal to the first and second data lines in response to a first control signal.

In an embodiment, the display apparatus may further include: a second gate line adjacent to the first gate line and extending in the second direction; a third data line adjacent to the first data line and extending in the second direction; a fourth data line adjacent to the second data line and extending in the second direction; a third sub-pixel electrically connected to the third data line; and a fourth sub-pixel electrically connected to the fourth data line.

In an embodiment, the first to fourth data lines may be formed in a same layer and may include a same material.

In an embodiment, each of the first and second sub-pixels may include a first electrode, a second electrode facing the first electrode, and an organic light emitting layer between the first electrode and the second electrode.

In an embodiment, the display apparatus may further include fifth to eighth data lines that are adjacent to each other and extend in the second direction, the data driver further including a demultiplexer configured to provide the data signals to the first to eighth data lines, and the demultiplexer may be configured to provide the data signals to the first to fourth data lines in response to a first control signal, and to provide the data signals to the fifth to eighth data lines in response to a second control signal.

In an embodiment, the first and second data lines may be located between the first sub-pixel and the second sub-pixel.

In an embodiment, the display apparatus may further include an overlapping line extending in the first direction, electrically connected to the row line, and overlapping the row line.

According to an example embodiment of the present invention, a display apparatus includes: first and second data lines electrically connected to first and second switching elements, respectively, and configured to transmit data signals in response to a first control signal; third and fourth data lines electrically connected to third and fourth switching elements, respectively, and configured to transmit data signals in response to a second control signal; a first transmit line electrically connected to the first switching element and the third switching element; and a second transmit line electrically connected to the second switching element and the fourth switching element. The first data line and the second data line are adjacent to each other, and the third data line and the fourth data line are adjacent to each other.

In an embodiment, the display apparatus may further include a first gate line spaced from the first and second data lines and extending in parallel with the first and second data lines.

In an embodiment, the display apparatus may further include: a data driver configured to provide the data signals to the first and second data lines; and a gate driver configured to provide a gate signal to the first gate line. The data driver and the gate driver may be located at a same side of the display apparatus, or may be located at opposite sides of the display apparatus.

In an embodiment, the display apparatus may further include a voltage line between the first gate line and the first and second data lines and extending in parallel with the first and second data lines.

In an embodiment, the voltage line may include a power voltage line or an initialization voltage line.

According to an example embodiment of the present invention, a display apparatus includes: a plurality of pixels; a data driver adjacent to an area where the pixels are located and configured to provide data signals to the pixels; a gate driver adjacent to the data driver and configured to provide gate signals to the pixels; first and second data lines adjacent to each other and extending in parallel with each other; a gate line spaced from the first and second data lines and extending in parallel with the first and second data lines; and a voltage line between the gate line and the first and second data lines.

Therefore, according to one or more aspects of example embodiments of the present invention, coupling capacitance between data lines and gate lines extending in a same direction may be reduced, so that display quality of an organic light emitting display apparatus may be improved.

### BRIEF DESCRIPTION OF THE DRAWINGS

The above and other aspects and features of the present invention will become more apparent from the following detailed description of example embodiments with reference to the accompanying drawings, in which:

FIG. 1 is a block diagram illustrating an organic light emitting display apparatus according to an example embodiment of the present invention;

FIG. 2 is a plan view illustrating two sub-pixels that are adjacent to each other in a display panel of FIG. 1;

FIG. 3 is a circuit diagram of the sub-pixels of FIG. 2;

FIG. 4 is a diagram illustrating the connection relationship of data lines of the display panel of FIG. 2;

FIG. 5 is a diagram illustrating the connection relationship of data lines of the organic light emitting display apparatus according to an example embodiment of the present invention;

FIG. 6 is a diagram illustrating the connection relationship of data lines of the display apparatus according to an example embodiment of the present invention; and

FIGS. 7A to 11B are plan views or cross-sectional views illustrating a method of manufacturing an organic light emitting display apparatus according to an example embodiment of the present invention.

### DETAILED DESCRIPTION

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section.

Thus, a first element, component, region, layer or section described below could be termed a second element, component, region, layer or section, without departing from the spirit and scope of the present invention.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

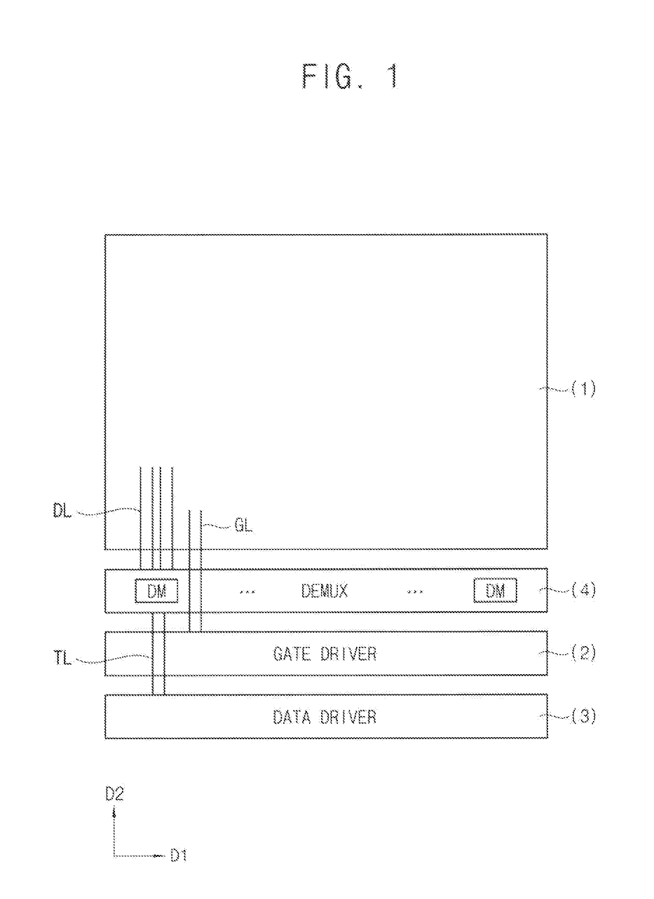

FIG. 1 is a block diagram illustrating an organic light emitting display apparatus according to an example embodiment of the present invention.

Referring to FIG. 1, the organic light emitting display apparatus may include a pixel panel 1, a gate driver 2, a data driver 3, a demultiplexing unit (e.g., a demultiplexer) 4, and a timing controller.

The display panel 1 may include a plurality of pixels. The plurality of pixels may be arranged in a matrix structure. For example, the plurality of pixels may be arranged in the matrix structure having N rows and M columns crossing each other, where N and M are positive integers.

The gate driver 2 may generate and provide gate signals (e.g., sequentially) to the display panel 1. For example, when a gate signal is applied to a gate line GL, a data signal may be applied to the pixel that is connected to the gate line GL.

The data driver 3 may output (e.g., alternately output) a first data signal and a second data signal to the display panel 1. That is, the first data signal and the second data signal may be output (e.g., sequentially output) during one horizontal period.

As illustrated in FIG. 1, the organic light emitting display device may have a demultiplexing structure. Thus, the demultiplexing unit 4 may be located between the display panel 1 and the data driver 3, and the demultiplexing unit 4 may include a plurality of demultiplexers DM. The demultiplexing unit 4 may receive (e.g., alternately receive) the first data signal and the second data signal from the data driver 3, and may apply (e.g., alternately apply) the first data signal and the second data signal to the pixels. For example, as the data driver 3 outputs (e.g., alternately outputs) the first data signal and the second data signal via an output-line TL (e.g., as the data driver 3 sequentially outputs the first data signal and the second data signal via a first output-line TL during one horizontal period), the demultiplexer DM coupled to the output-line TL may apply (e.g., alternately apply) the first data signal and the second data signal to the pixels.

The timing controller 5 may control the gate driver 2, the data driver 3, and the demultiplexing unit 4. The timing controller 5 may generate a first control signal, a second control signal, and a third control signal, and may control the gate driver 2, the data driver 3, and the demultiplexing unit 4 by providing the first control signal, the second control signal, and the third control signal to the gate driver 2, the data driver 3, and the demultiplexing unit 4, respectively. Specifically, the timing controller 5 may provide the first control signal to the gate driver 2. Thus, the gate driver 2 may output (e.g., sequentially output) the gate signals to the display panel 1. In addition, the timing controller 5 may provide the second control signal to the data driver 3. Thus, the data driver 3 may output (e.g., alternately output) the first and second data signals to the display panel 1. Further, the timing controller 5 may provide the third control signal to the demultiplexing unit 4. Thus, the demultiplexing unit 4 may apply (e.g., alternately apply) the first data signal and the second data signal to the pixels.

In some embodiments, the organic light emitting display apparatus may further include a light emitting control unit (e.g., a light emitting controller) configured to output an emission control signal.

Each of the gate driver 2, the data driver 3, the demultiplexing unit 4, and the timing controller may be located at one side (e.g., a same side) of the display panel 1. Accordingly, non-display areas at three sides of the display apparatus, except for the one side at which the gate driver 2, the data driver 3, the demultiplexing unit 4, and the timing controller are located, may be reduced or minimized.

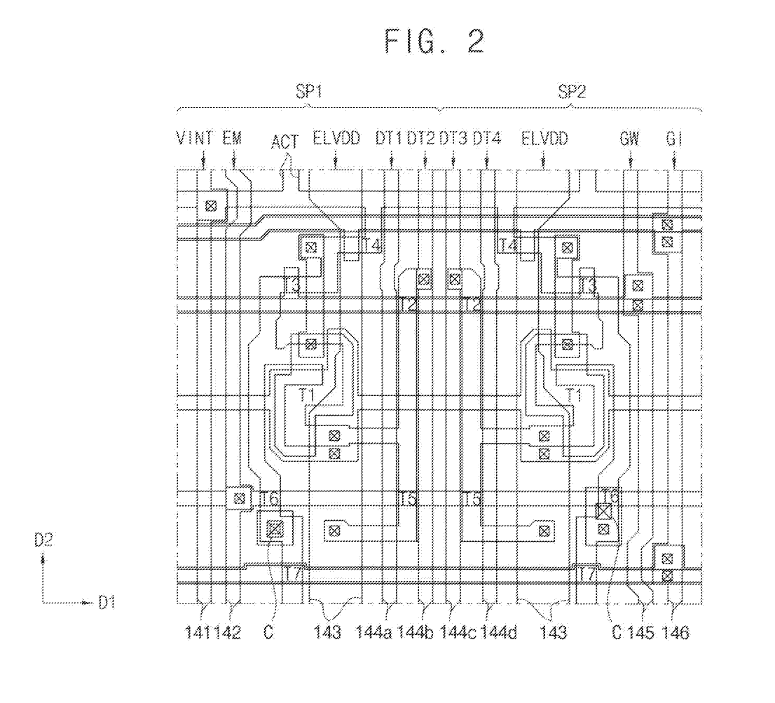

FIG. 2 is a plan view illustrating two sub-pixels that are adjacent to each other in a display panel of FIG. 1.

Referring to FIG. 2, a first sub-pixel SP1 and a second sub-pixel SP2 may be adjacent to each other in a first direction D1. The first and second sub-pixels SP1 and SP2 may include an active pattern ACT, an initialization voltage line 141, an emission control line 142, a power voltage line 143, a first data line 144a, a second data line 144b, a third data line 144c, a fourth data line 144d, a first gate line 145, and a second gate line 146.

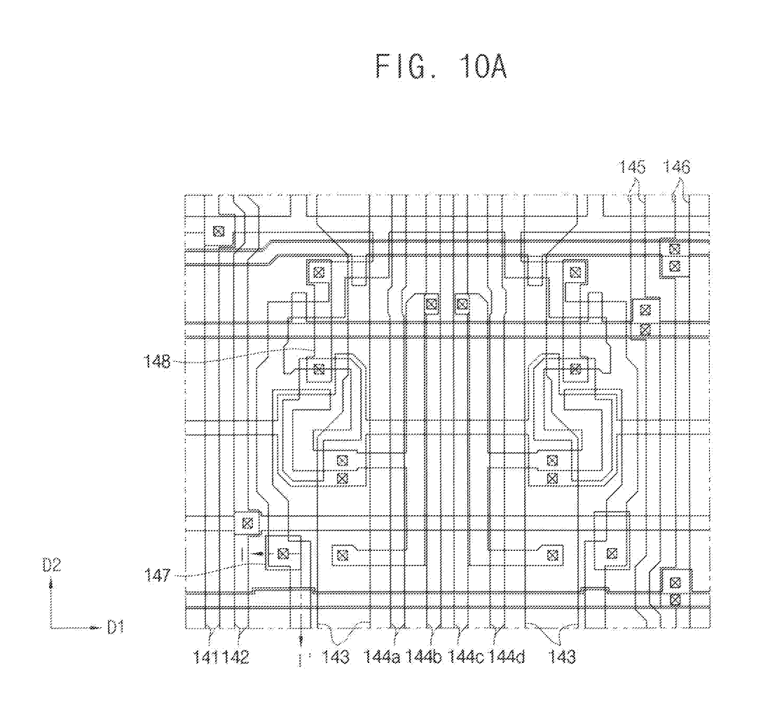

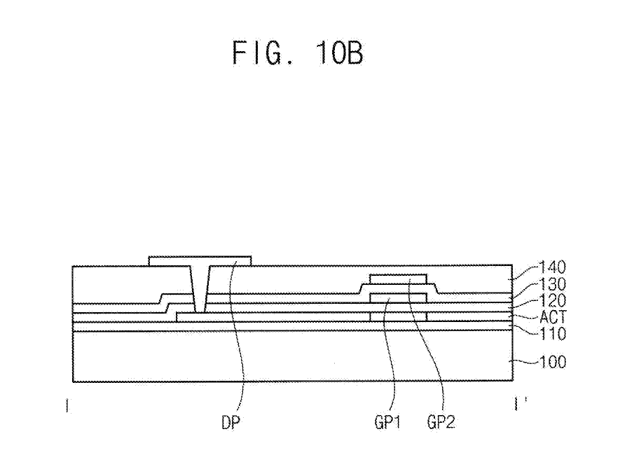

The active pattern ACT may extend in the first direction D1 and a second direction D2, which is perpendicular or substantially perpendicular to the first direction D1. The active pattern ACT may include channel areas, source areas, and drain areas of each of first to seventh transistors T1, T2, T3, T4, T5, T6 and T7. The source and drain areas may be doped by an impurity, such that the source and drain areas may have a higher electrical conductivity than those of other regions of the active pattern ACT. The active pattern ACT may be electrically connected to a first electrode of an organic light emitting diode through a first connecting electrode (see 147 of FIG. 10A) and a via hole C.

The initialization voltage line 141 may extend in the second direction D2. The initialization voltage line 141 may be electrically connected to the active pattern ACT, which extends in the first direction D1, through a contact hole. Thus, the initialization voltage line 141 may have a mesh structure in the first direction D1 and the second direction D2. An initialization voltage VINT may be applied to the initialization voltage line 141.

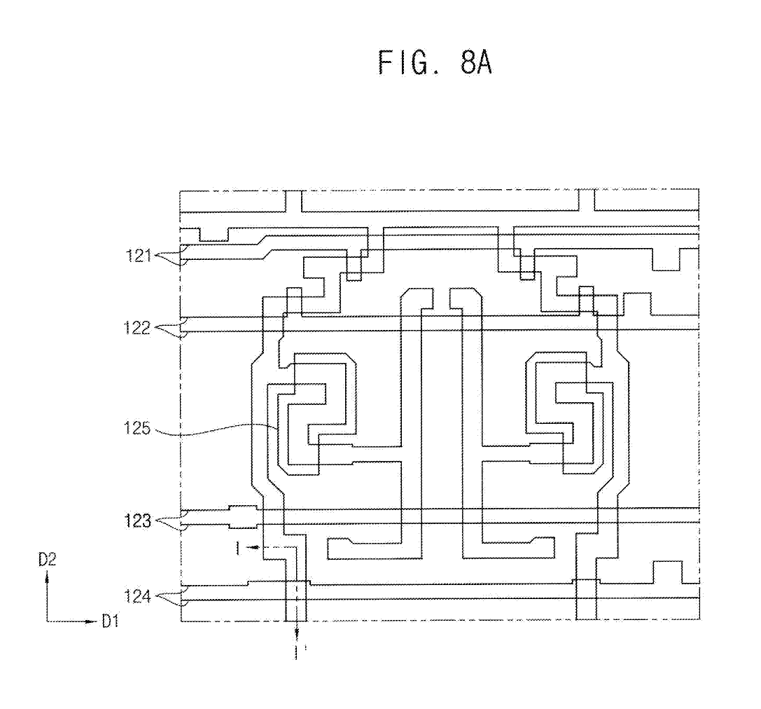

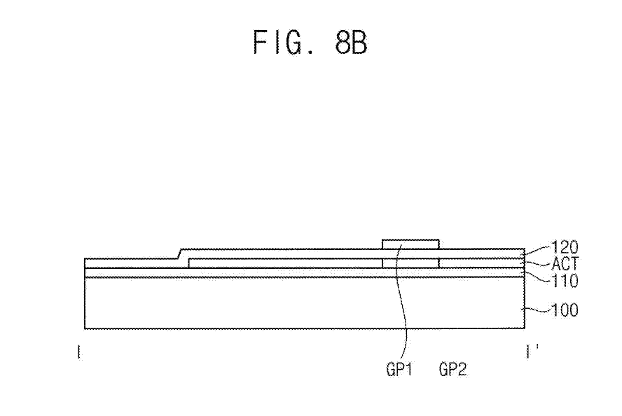

The emission control line 142 may be adjacent to the initialization voltage line 141, and may extend in the second direction D2. The emission control line 142 may be electrically connected to a third row line (see 123 of FIG. 8A), which extends in the first direction D1, through a contact hole. An emission control signal EM may be provided to the emission control line 142. The third row line may include a gate electrode of the sixth transistor T6 and a gate electrode of the fifth transistor T5.

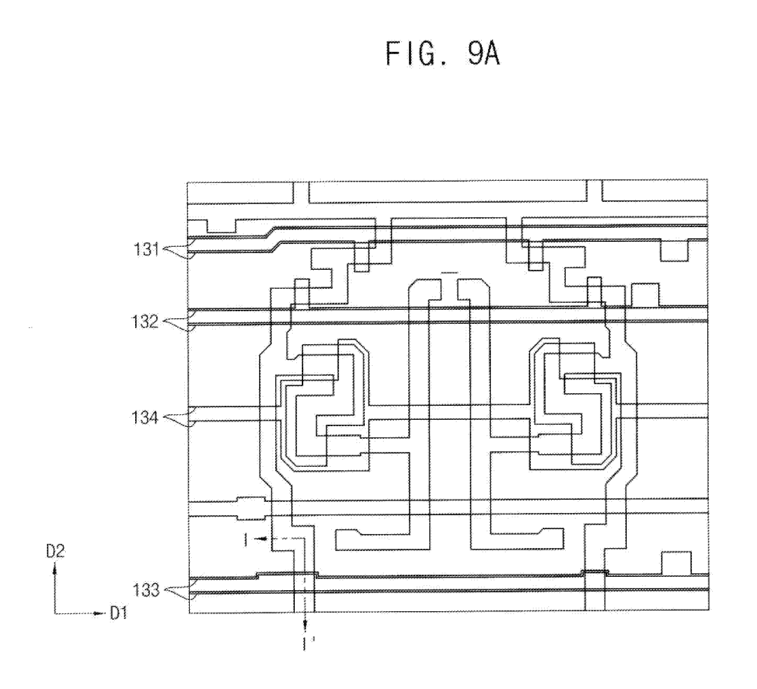

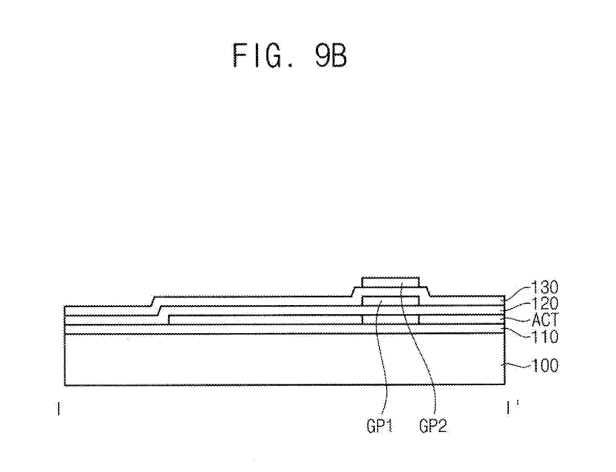

The power voltage line 143 may be spaced from the emission control line 142 along the first direction D1, and may extend in the second direction D2. The power voltage line 143 may be electrically connected to a storage line (see 134 of FIG. 9A) through a contact hole. In addition, the power voltage line 143 may be electrically connected to the active pattern ACT through a contact hole. The power voltage line 143 may be located for each of the first sub-pixel SP1 and the second sub-pixel SP2. A first power voltage ELVDD may be applied to the power voltage line 143.

The first data line 144a may be spaced from the power voltage line 143 along the first direction D1, and may extend in the second direction D2. The first data line 144a may be electrically connected to a pixel that is adjacent to the first sub-pixel SP1 along the second direction D2. A first data signal DT1 may be applied to the first data line 144a.

The second data line 144b may be adjacent to the first data line 144a, and may extend in the second direction D2. The second data line 144b may be electrically connected to the active pattern ACT through a contact hole. A second data signal DT2 may be applied to the second data line 144b.

The third data line 144c may be adjacent to the second data line 144b, and may extend in the second direction D2. The third data line 144c may be electrically connected to the active pattern ACT through a contact hole. A third data signal DT3 may be applied to the third data line 144c.

The fourth data line 144d may be adjacent to the third data line 144c, and may extend in the second direction D2. The fourth data line 144d may be electrically connected to a pixel that is adjacent to the second sub-pixel SP2 along the second direction D2. A fourth data signal DT4 may be applied to the fourth data line 144d.

The first gate line 145 may be spaced from the power voltage line 143 along the first direction D1, and may extend in the second direction D2. The first gate line 145 may be electrically connected to a second row line (see 122 of FIG. 8A) through a contact hole. A gate signal GW may be applied to the first gate line 145.

The second gate line 146 may be adjacent to the first gate line 145, and may extend in the second direction D2. The second gate line 146 may be electrically connected to a first row line and a fourth row line (see 121 and 124 of FIG. 8A) through respective contact holes. A data initialization signal GI may be applied to the second gate line 146.

Accordingly, the first sub-pixel SP1 and the second sub-pixel SP2 may have a mirrored or substantially mirrored circuit structure with the first to fourth data lines 144a, 144b, 144c, and 144d located therebetween.

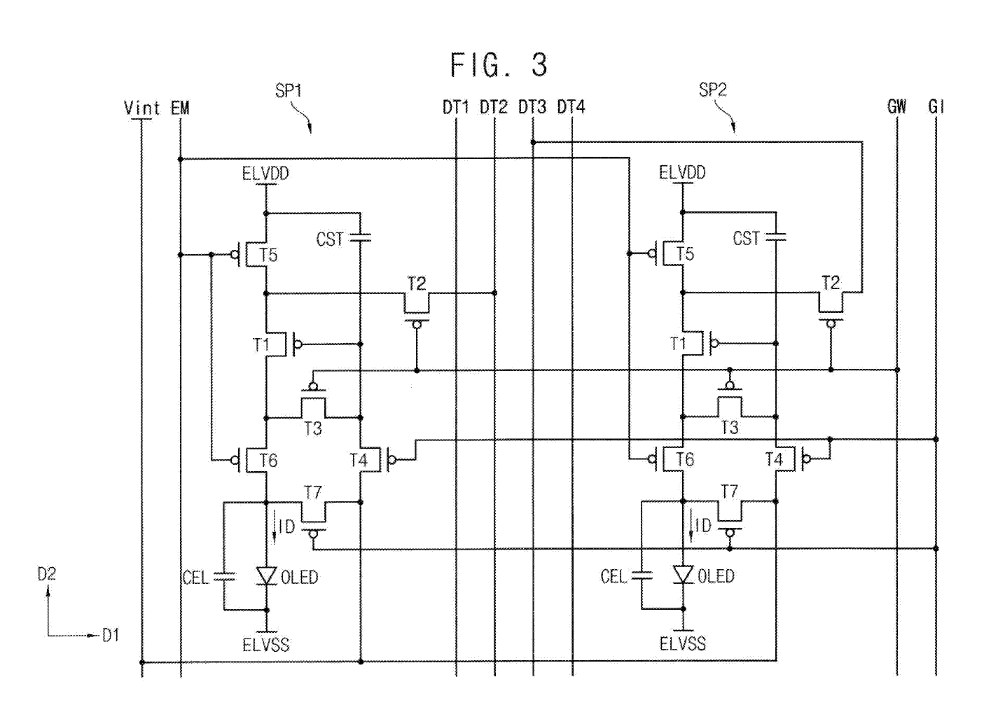

FIG. 3 is a circuit diagram of the sub-pixels of FIG. 2.

Referring to FIG. 3, a first sub-pixel SP1 may include an organic light emitting diode OLED, a first transistor T1, a second transistor T2, a third transistor T3, a storage capacitor CST, a fourth transistor T4, a fifth transistor T5, a sixth transistor T6, and a seventh transistor T7. In addition, the first sub-pixel SP1 may further include a diode parallel capacitor CEL. The diode parallel capacitor CEL may be a parasitic capacitor.

The organic light emitting diode OLED may emit light based on a driving current ID. The organic light emitting diode OLED may include a first electrode and a second electrode. In one example embodiment, a second power voltage ELVSS may be applied to the second electrode of the organic light emitting diode OLED. In one example embodiment, the first electrode of the organic light emitting diode OLED may be an anode electrode, and the second electrode of the organic light emitting diode OLED may be a cathode electrode. In another example embodiment, the first electrode of the organic light emitting diode OLED may be the cathode electrode, and the second electrode of the organic light emitting diode OLED may be the anode electrode.

The first transistor T1 may include a gate electrode, a first electrode, and a second electrode. In one example embodiment, the first electrode of the first transistor T1 may be a source electrode, and the second electrode of the first transistor T1 may be a drain electrode. In another example embodiment, the first electrode of the first transistor T1 may be a drain electrode, and the second electrode of the first transistor T1 may be a source electrode.

The first transistor T1 may generate the driving current ID. In one example embodiment, the first transistor T1 may operate in a saturation region. In this case, the first transistor T1 may generate the driving current ID based on a voltage difference between the gate electrode and the source electrode of the first transistor T1. A grayscale (e.g., gray level) may be presented based on the driving current ID provided to the organic light emitting diode OLED. In another example embodiment, the first transistor T1 may operate in a linear region. In this case, the grayscale (e.g., gray level) may be presented based on a time length during which the driving current ID is provided to the organic light emitting diode OLED.

The second transistor T2 may include a gate electrode, a first electrode, and a second electrode. A gate signal GW may be applied to the gate electrode. A second data signal DT2 may be applied to the first electrode. The second electrode may be connected to the first electrode of the first transistor T1. In one example embodiment, the first electrode of the second transistor T2 may be a source electrode, and the second electrode of the second transistor T2 may be a drain electrode. In another example embodiment, the first electrode of the second transistor T2 may be a drain electrode, and the second electrode of the second transistor T2 may be a source electrode.

The second transistor T2 may provide the second data signal DT2 to the first electrode of the first transistor T1 while the gate signal GW is activated. The second transistor T2 may operate in the linear region.

The third transistor T3 may include a gate electrode, a first electrode, and a second electrode. The gate signal GW may be applied to the gate electrode. The first electrode of the third transistor T3 may be connected to the second electrode of the first transistor T1. The second electrode of the third transistor T3 may be connected to the gate electrode of the first transistor T1. In one example embodiment, the first electrode of the third transistor T3 may be a source electrode, and the second electrode of the third transistor T3 may be a drain electrode. In another example embodiment, the first electrode of the third transistor T3 may be a drain electrode, and the second electrode of the third transistor T3 may be a source electrode.

The third transistor T3 may connect the gate electrode of the first transistor T1 to the second electrode of the first transistor T1 while the gate signal GW is activated. The third transistor T3 may operate in a linear region. Thus, the third transistor T3 may form a diode connection of (e.g., diode-couple) the first transistor T1 while the gate signal GW is activated. A voltage difference between the first electrode of the first transistor T1 and the gate electrode of the first transistor T1 (e.g., a threshold voltage of the first transistor T1) may occur by the diode connection. Thus, a sum voltage of the second data signal DT2 provided to the first electrode of the first transistor T1 and the voltage difference (e.g., the threshold voltage) may be applied to the gate electrode of the first transistor T1 while the gate signal GW is activated. Thus, the second data signal DT2 may be compensated by as much as the threshold voltage of the first transistor T1. The compensated second data signal DT2 may be applied to the gate electrode of the first transistor T1. Accordingly, uniformity of the driving current ID may be improved by reducing a deviation of the threshold voltage of the first transistor T1 by the above compensation.

The storage capacitor CST may include a first electrode to which a first power voltage ELVDD is applied, and a second electrode connected to the gate electrode of the first transistor T1. The storage capacitor CST may maintain or substantially maintain a voltage level of the gate electrode of the first transistor T1 while the gate signal GW is inactivated. An emission signal EM may be activated when (or while) the gate signal GW is inactivated. The driving current ID generated by the first transistor T1 may be provided to the organic light emitting diode OLED when (or while) the emission signal EM is activated. Therefore, the driving current ID generated by the first transistor T1 may be provided to the organic light emitting diode OLED based on the voltage level that is maintained or substantially maintained by the storage capacitor CST.

The fourth transistor T4 may include a gate electrode, a first electrode, and a second electrode. A data initialization signal GI may be applied to the gate electrode of the fourth transistor T4. An initialization voltage Vint may be applied to the first electrode of the fourth transistor T4. The second electrode of the fourth transistor T4 may be connected to the gate electrode of the first transistor T1. In one example embodiment, the first electrode of the fourth transistor T4 may be a source electrode, and the second electrode of the fourth transistor T4 may be a drain electrode. In another example embodiment, the first electrode of the fourth transistor T4 may be a drain electrode, and the second electrode of the fourth transistor T4 may be a source electrode.

The fourth transistor T4 may apply the initialization voltage Vint to the gate electrode of the first transistor T1 when (or while) the data initialization signal GI is activated. The fourth transistor T4 may operate in the linear region. Thus, the fourth transistor T4 may initialize the gate electrode of the first transistor T1 to the initialization voltage Vint when (or while) the data initialization signal GI is activated. In one example embodiment, a voltage level of the initialization voltage Vint may be lower than a voltage level of the second data signal DT2 that is maintained or substantially maintained by the storage capacitor CST during a previous frame. In this case, the initialization voltage Vint may be applied to the gate electrode of the first transistor T1, and the first transistor T1 may be a p-channel metal oxide semiconductor (PMOS)-type transistor. In another example embodiment, a voltage level of the initialization voltage Vint may be higher than the voltage level of the second data signal DT2 that is maintained or substantially maintained by the storage capacitor CST during the previous frame. In this case, the initialization voltage Vint may be applied to the gate electrode of the first transistor T1, and the first transistor T1 may be an n-channel metal oxide semiconductor (NMOS)-type transistor.

In one example embodiment, the data initialization signal GI may be the same or substantially the same as the gate signal GW that is applied to a previous horizontal line. For example, when the data initialization signal GI is applied to pixels located in an (n)th row, the data initialization signal GI may be the same or substantially the same as the gate signal GW applied to pixels located in an (n−1)th row. Thus, the data initialization signal GI that is activated may be applied to pixels located in the (n)th row by applying the gate signal GW that is activated to pixels located in the (n−1)th row. Thus, the gate electrode of the first transistor T1 included in pixels located in the (n)th row may be initialized as the initialization voltage Vint when the data signal is applied to pixels located in the (n−1)th row.

The fifth transistor T5 may include a gate electrode, a first electrode, and a second electrode. The emission signal EM may be applied to the gate electrode of the fifth transistor T5. The first power voltage ELVDD may be applied the first electrode of the fifth transistor T5. The second electrode of the fifth transistor T5 may be connected to the first electrode of the first transistor T1. In one example embodiment, the first electrode of the fifth transistor T5 may be a source electrode, and the second electrode of fifth transistor T5 may be a drain electrode. In another example embodiment, the first electrode of the fifth transistor T5 may be a drain electrode, and the second electrode of the fifth transistor T5 may be a source electrode.

The fifth transistor T5 may apply the first power voltage ELVDD to the first electrode of the first transistor T1 when (or while) the emission signal EM is activated. The fifth transistor T5 may not apply the first power voltage ELVDD when (or while) the emission signal EM is inactivated. The fifth transistor T5 may operate in the linear region. The fifth transistor T5 may apply the first power voltage ELVDD to the first electrode of the first transistor T1 when (or while) the emission signal EM is activated, such that the first transistor T1 generates the driving current ID. In addition, the fifth transistor T5 may not apply the first power voltage ELVDD when (or while) the emission signal EM is inactivated, such that the second data signal DT2 applied to the first electrode of the first transistor T1 is applied to the gate electrode of the first transistor T1.

The sixth transistor T6 may include a gate electrode, a first electrode, and a second electrode. The emission signal EM may be applied to the gate electrode of the sixth transistor T6. The first electrode of the sixth transistor T6 may be connected to the second electrode of the first transistor T1. The second electrode of the sixth transistor T6 may be connected to the first electrode of the organic light emitting diode OLED. In one example embodiment, the first electrode of the sixth transistor T6 may be a source electrode, and the second electrode of sixth transistor T6 may be a drain electrode. In another example embodiment, the first electrode of the sixth transistor T6 may be a drain electrode, and the second electrode of the sixth transistor T6 may be a source electrode.

The sixth transistor T6 may provide the driving current ID generated by the first transistor T1 to the organic light emitting diode OLED when (or while) the emission signal EM is activated. The sixth transistor T6 may operate in the linear region. Thus, the sixth transistor T6 may provide the driving current ID generated by the first transistor T1 to the organic light emitting diode OLED when (or while) the emission signal EM is activated, such that the organic light emitting diode OLED emits light. In addition, the sixth transistor T6 may disconnect the first transistor T1 from the organic light emitting diode OLED when (or while) the emission signal EM is inactivated, such that the compensated second data signal DT2 applied to the second electrode of the first transistor T1 is applied to the gate electrode of the first transistor T1.

The seventh transistor T7 may include a gate electrode, a first electrode and a second electrode. A diode initialization signal (e.g., the data initialization signal GI) may be applied to the gate electrode of the seventh transistor T7. The initialization voltage Vint may be applied to the first electrode of the seventh transistor T7. The second electrode of the seventh transistor T7 may be connected to the first electrode of the organic light emitting diode OLED. In one example embodiment, the first electrode of the seventh transistor T7 may be a source electrode, and the second electrode of seventh transistor T7 may be a drain electrode. In another example embodiment, the first electrode of the seventh transistor T7 may be a drain electrode, and the second electrode of the seventh transistor T7 may be a source electrode.

The seventh transistor T7 may apply the initialization voltage Vint to the first electrode of the organic light emitting diode OLED when (or while) the diode initialization signal is activated. The seventh transistor T7 may operate in the linear region. Thus, the seventh transistor T7 may initialize the first electrode of the organic light emitting diode OLED to the initialization voltage Vint when (or while) the diode initialization signal is activated.

An initial changing amount of the diode parallel capacitor CEL may be calculated according to Equation 1 below:

Qi=CEL×(VINT−ELVSS) Equation 1

wherein, Qi is the initial changing amount of the diode parallel capacitor, CEL is a capacitance of the diode parallel capacitor, VINT is a voltage level of the initialization voltage, and ELVSS is a voltage level of the second power voltage.

In one example embodiment, the data initialization signal GI and the diode initialization signal may be the same signal. An initialization operation of the gate electrode of the first transistor T1 may not affect an initialization operation of the first electrode of the organic light emitting diode OLED. Therefore, the data initialization signal GI may be used as the diode initialization signal, thereby improving the manufacturing efficiency.

A voltage difference between the electrodes of the organic light emitting diode OLED may be lower than a threshold voltage of the organic light emitting diode OLED when the organic light emitting diode OLED does not emit light. The organic light emitting diode OLED may emit light when the voltage difference is higher than the threshold voltage. Therefore, the voltage difference may reach (e.g., be increased to) the threshold voltage, and light may be emitted when a threshold capacitance is charged in the diode parallel capacitor CEL.

The threshold capacitance may be calculated according to Equation 2 below:

Qc=CEL×Vth Equation 2

wherein, Qc is the threshold capacitance, CEL is the capacitance of the diode parallel capacitor, and Vth is the threshold voltage of the organic light emitting diode OLED.

In one example embodiment, the driving current ID may not be equal to zero when the organic light emitting diode OLED displays a black colored light (e.g., the grayscale or gray level is equal to or substantially equal to zero), because of a leakage current generated from the first transistor T1. However the leakage current may flow through the diode parallel capacitor CEL, instead of through the organic light emitting diode OLED, until the voltage difference between the electrodes of the organic light emitting diode OLED reaches (e.g., increases to) the threshold voltage. The organic light emitting diode OLED may not emit light while the diode parallel capacitor CEL is charged with the leakage current, until the diode parallel capacitor CEL is charged with the threshold capacitance.

For example, if the leakage current has a fixed amount, the initialization voltage VINT may be calculated according to Equation 3 below:

$$VINT \leq ELVSS + Vth - \frac{{I}_{leak} \times t}{CEL} \qquad Equation 3$$

wherein, VINT is a voltage level of the initialization voltage, ELVSS is a voltage level of the second power voltage, Vth is the threshold voltage of the organic light emitting diode OLED, Iₗₑₐₖ is an amount of the leakage current, t is a time length during which the OLED does not emit light during one frame, and CEL is a capacitance of the diode parallel capacitor.

The second sub-pixel SP2 may be located adjacent to the first sub-pixel SP1 along the first direction D1. The second sub-pixel SP2 may have the same or substantially the same configuration as that of the first sub-pixel SP1, except that the second sub-pixel SP2 receives a third data signal DT3 at the second transistor T2 instead of the second data signal DT2.

A first data signal DT1 and a fourth data signal DT4 may be provided to two sub-pixels that are adjacent to the first sub-pixel SP1 and second sub-pixel SP2 along the second direction D2, respectively. The second direction D2 is perpendicular or substantially perpendicular to the first direction D1.

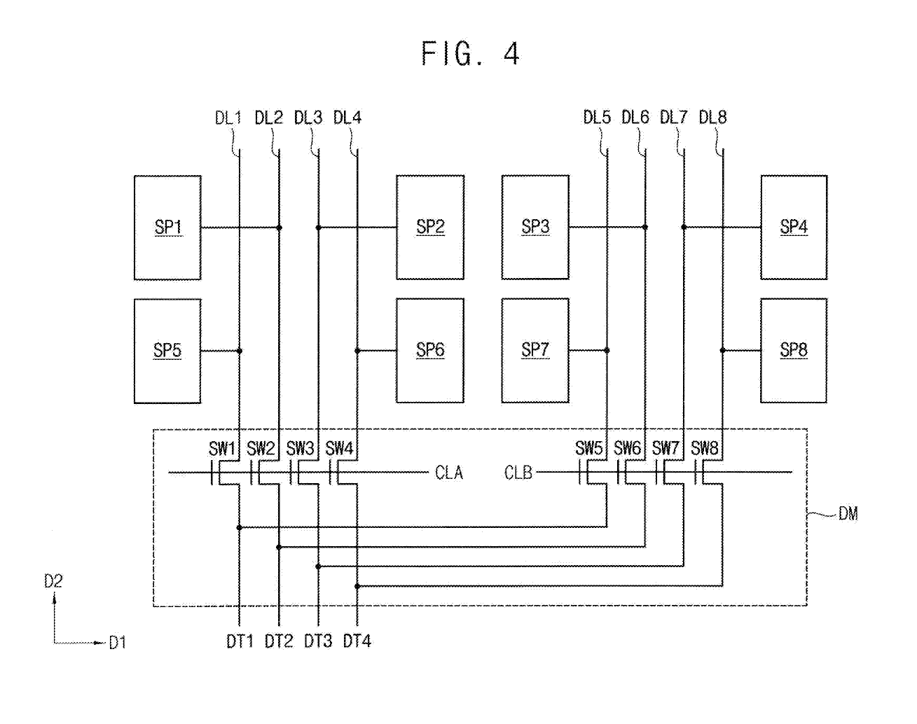

FIG. 4 is a diagram illustrating the connection relationship of data lines of the display panel of FIG. 2.

Referring to FIG. 4, first to eighth sub-pixels SP1 to SP8 may be arranged in a 2*4 matrix form. First to fourth data lines DL1 to DL4 may be located between the first sub-pixel SP1 and the second sub-pixels SP2, and located between the fifth sub-pixel SP5 and the sixth sub-pixel SP6. Fifth to eighth data lines DL5 to DL8 may be located between the third sub-pixel SP3 and the fourth sub-pixel SP4, and located between the seventh sub-pixel SP7 and the eighth sub-pixel SP8.

The first sub-pixel SP1 may be electrically connected to the second data line DL2. The second sub-pixel SP2 may be electrically connected to the third data line DL3. The third sub-pixel SP3 may be electrically connected to the sixth data line DL6. The fourth sub-pixel SP4 may be electrically connected to the seventh data line DL7. The fifth sub-pixel SP5 may be electrically connected to the first data line DL1. The sixth sub-pixel SP6 may be electrically connected to the fourth data line DL4. The seventh sub-pixel SP7 may be electrically connected to the fifth data line DL5. The eighth sub-pixel SP8 may be electrically connected to the eighth data line DL8.

A demultiplexer DM may receive first to fourth data signals DT1 to DT4, and may output the data signals to the first to fourth data lines DL1 to DL4 and the fifth to eighth data lines DL5 to DL8. The data signals outputted to the first to eighth data lines DL1 to DL8 may be formed from the first to fourth data signals DT1 to DT4 through time division by the demultiplexer DM.

For example, the demultiplexer DM may provide data signals to the first data line DL1 and the fifth data line DL5 formed from the first data signal DT1 through time division in response to a first control signal CLA and a second control signal CLB. The demultiplexer DM may provide data signals to the second data line DL2 and the sixth data line DL6 formed from the second data signal DT2 through time division in response to the first control signal CLA and the second control signal CLB. The demultiplexer DM may provide data signals to the third data line DL3 and the seventh data line DL7 formed from the third data signal DT3 through time division in response to the first control signal CLA and the second control signal CLB. The demultiplexer DM may provide data signals to the fourth data line DL4 and the eighth data line DL8 formed from the fourth data signal DT4 through time division in response to the first control signal CLA and the second control signal CLB.

For example, the first to fourth data lines DL1 to DL4 may be electrically connected to first to fourth switching elements SW1 to SW4, respectively, which are turned on by the first control signal CLA of the demultiplexer DM. The fifth to eighth data lines DL5 to DL8 may be electrically connected to fifth to eighth switching elements SW5 to SW8, respectively, which are turned on by the second control signal CLB of the demultiplexer DM. For example, the first control signal CLA may have an enabling level (e.g., a high level) during ½ of one horizontal period, and the second control signal CLB may have an enabling level (e.g., a high level) during the other ½ of the one horizontal period.

Accordingly, data signals may be provided to the first to fourth data lines DL1 to DL4 in response to the first control signal CLA during the same period (e.g., at the same time), so that display quality degradation caused by parasitic capacitance between adjacent data lines may be reduced. Similarly, data signals may be provided to the fifth to eighth data lines DL5 to DL8 in response to the second control signal CLB during the same period (e.g., at the same time), so that display quality degradation caused by parasitic capacitance between adjacent data lines may be reduced.

Each of the first to eighth sub-pixels SP1 to SP8 may have one of red, green, and blue colors. For example, the first sub-pixel SP1 may have a red color, the second sub-pixel SP2 may have a green color, the third sub-pixel SP3 may have a blue color, the fourth sub-pixel SP4 may have a green color, the fifth sub-pixel SP5 may have a blue color, the sixth sub-pixel SP6 may have a green color, the seventh sub-pixel SP7 may have a red color, and the eighth sub-pixel SP8 may have a green color.

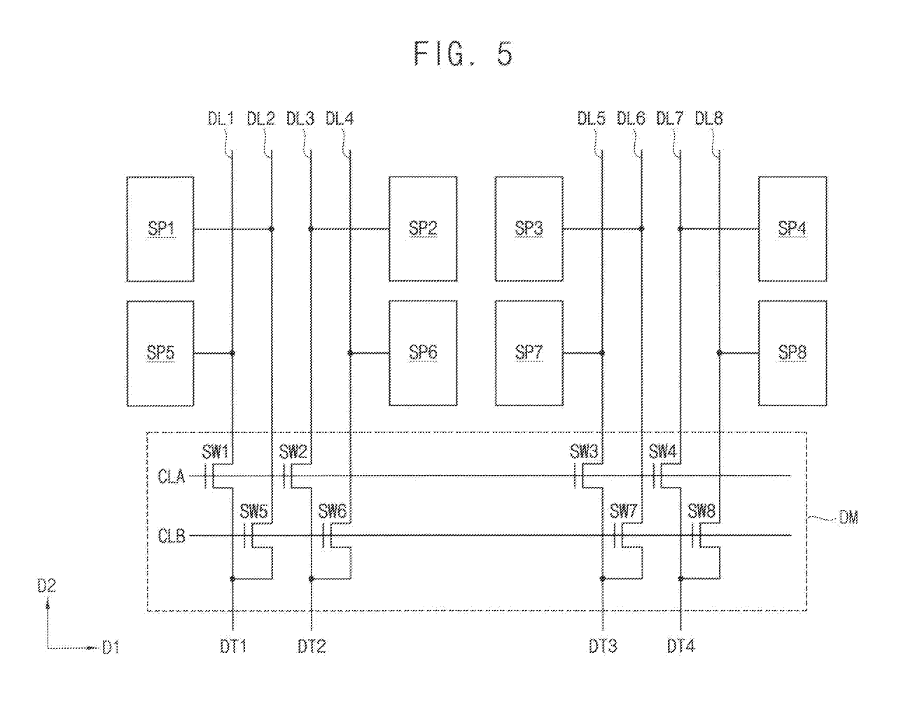

FIG. 5 is a diagram illustrating the connection relationship of data lines of the organic light emitting display apparatus according to an example embodiment of the present invention.

Referring to FIG. 5, the organic light emitting display apparatus has the same or substantially the same structure as that of the organic light emitting display apparatus of FIGS. 1, 2, and 3, except for a demultiplexer DM. Thus, repeat descriptions may be briefly described or may be omitted.

First to eighth sub-pixels SP1 to SP8 may be arranged in a 2*4 matrix form. First to fourth data lines DL1 to DL4 may be located between the first sub-pixel SP1 and the second sub-pixels SP2, and may be located between the fifth sub-pixel SP5 and the sixth sub-pixel SP6. Fifth to eighth data lines DL5 to DL8 may be located between the third sub-pixel SP3 and the fourth sub-pixel SP4, and may be located between the seventh sub-pixel SP7 and the eighth sub-pixel SP8.

The first sub-pixel SP1 may be electrically connected to the second data line DL2. The second sub-pixel SP2 may be electrically connected to the third data line DL3. The third sub-pixel SP3 may be electrically connected to the sixth data line DL6. The fourth sub-pixel SP4 may be electrically connected to the seventh data line DL7. The fifth sub-pixel SP5 may be electrically connected to the first data line DL1. The sixth sub-pixel SP6 may be electrically connected to the fourth data line DL4. The seventh sub-pixel SP7 may be electrically connected to the fifth data line DL5. The eighth sub-pixel SP8 may be electrically connected to the eighth data line DL8.

The demultiplexer DM may receive the first data signal DT1, and may output data signals to the first and second data lines DL1 and DL2. The demultiplexer DM may receive the second data signals DT2, and may output data signals to the third and fourth data lines DL3 and DL4. The demultiplexer DM may receive the third data signal DT3, and may output data signals to the fifth and sixth data lines DL5 and DL6. The demultiplexer DM may receive the fourth data signals DT4, and may output data signals to the seventh and eighth data lines DL7 and DL8.

For example, the first, third, fifth, and seventh data lines DL1, DL3, DL5, and DL7 may be electrically connected to first to fourth switching elements SW1 to SW4, respectively, which are turned on by the first control signal CLA of the demultiplexer DM. The second, fourth, sixth, and eighth data lines DL2, DL4, DL6, and DL8 may be electrically connected to fifth to eighth switching elements SW5 to SW8, respectively, which are turned on by the second control signal CLB of the demultiplexer DM. For example, the first control signal CLA may have an enabling level (e.g., a high level) during ½ of one horizontal period, and the second control signal CLB may have an enabling level (e.g., a high level) during the other ½ of the one horizontal period.

Each of the first to eighth sub-pixels SP1 to SP8 may have one of red, green, and blue colors. For example, the first sub-pixel SP1 may have a red color, the second sub-pixel SP2 may have a green color, the third sub-pixel SP3 may have a blue color, the fourth sub-pixel SP4 may have a green color, the fifth sub-pixel SP5 may have a blue color, the sixth sub-pixel SP6 may have a green color, the seventh sub-pixel SP7 may have a red color, and the eighth sub-pixel SP8 may have a green color.

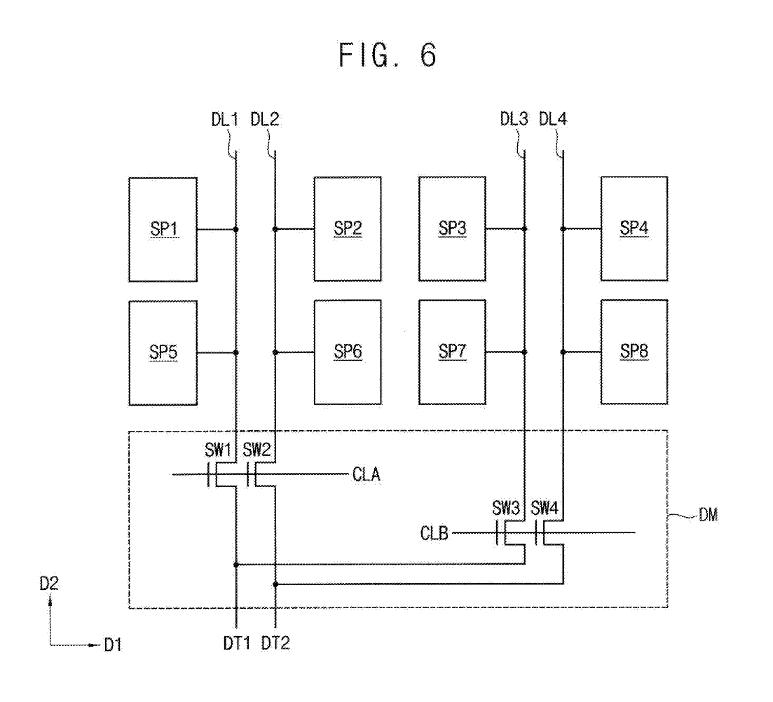

FIG. 6 is a diagram illustrating the connection relationship of data lines of the display apparatus according to an example embodiment of the present invention.

Referring to FIG. 6, first to eighth sub-pixels SP1 to SP8 may be arranged in a 2*4 matrix form. First and second data lines DL1 and DL2 may be located between the first sub-pixel SP1 and the second sub-pixels SP2, and may be located between the fifth sub-pixel SP5 and the sixth sub-pixel SP6. Third and fourth data lines DL3 to DL4 may be located between the third sub-pixel SP3 and the fourth sub-pixel SP4, and may be located between the seventh sub-pixel SP7 and the eighth sub-pixel SP8.

The first sub-pixel SP1 may be electrically connected to the first data line DL1. The second sub-pixel SP2 may be electrically connected to the second data line DL2. The third sub-pixel SP3 may be electrically connected to the third data line DL3. The fourth sub-pixel SP4 may be electrically connected to the fourth data line DL4. The fifth sub-pixel SP5 may be electrically connected to the first data line DL1. The sixth sub-pixel SP6 may be electrically connected to the second data line DL2. The seventh sub-pixel SP7 may be electrically connected to the third data line DL3. The eighth sub-pixel SP8 may be electrically connected to the fourth data line DL4.

The demultiplexer DM may receive first and second data signals DT1 and DT2, and may output data signals to the first to fourth data lines DL1 to DL4. The data signals outputted to the first to fourth data lines DL1 to DL4 may be formed from the first and second data signals DT1 and DT2 through time division by the demultiplexer DM.

The demultiplexer DM may provide data signals to the first data line DL1 and the third data line DL3 formed from the first data signal DT1 through time division in response to a first control signal CLA and a second control signal CLB. The demultiplexer DM may provide data signals to the second data line DL2 and the fourth data line DL4 formed from the second data signal DT2 through time division in response to the first control signal CLA and the second control signal CLB.

For example, the first and second data lines DL1 and DL2 may be electrically connected to first and second switching elements SW1 and SW2, respectively, which are turned on by the first control signal CLA of the demultiplexer DM. The third and fourth data lines DL3 to DL4 may be electrically connected to third and fourth switching elements SW3 and SW4, respectively, which are turned on by the second control signal CLB of the demultiplexer DM. For example, the first control signal CLA may have an enabling level (e.g., a high level) during ½ of one horizontal period, and the second control signal CLB may have an enabling level (e.g., a high level) during the other ½ of the one horizontal period.

Accordingly, data signals may be provided to the first and second data lines DL1 and DL2, which are adjacent each other, in response to the first control signal CLA during the same period (e.g., at the same time), so that display quality degradation caused by parasitic capacitance between adjacent data lines may be reduced. Similarly, data signals may be provided to the third and fourth data lines DL3 and DL4, which are adjacent each other, in response to the second control signal CLB during the same period (e.g., at the same time), so that display quality degradation caused by parasitic capacitance between adjacent data lines may be reduced.

Each of the first to eighth sub-pixels SP1 to SP8 may have one of red, green, and blue colors. For example, the first sub-pixel SP1 may have a red color, the second sub-pixel SP2 may have a green color, the third sub-pixel SP3 may have a blue color, the fourth sub-pixel SP4 may have a green color, the fifth sub-pixel SP5 may have a blue color, the sixth sub-pixel SP6 may have a green color, the seventh sub-pixel SP7 may have a red color, and the eighth sub-pixel SP8 may have a green color.

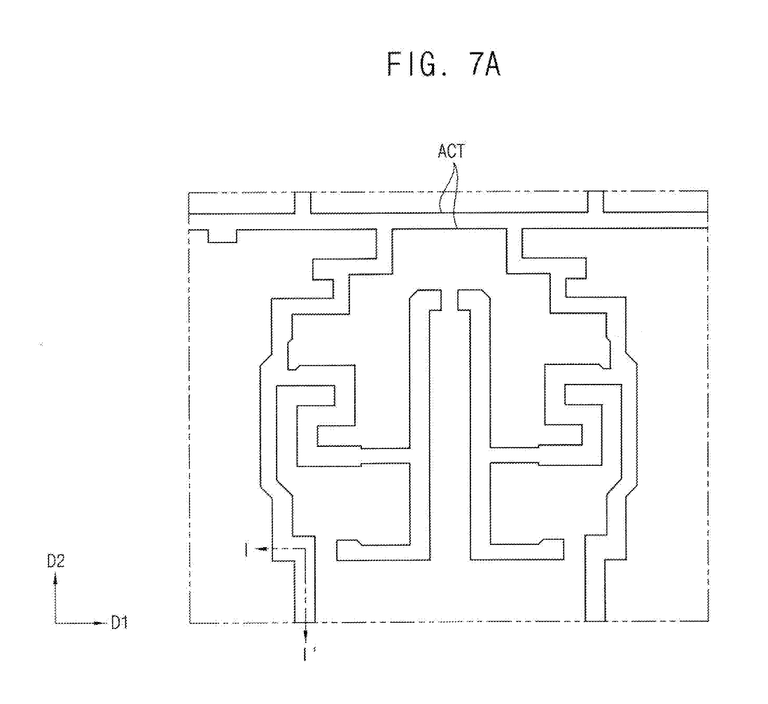

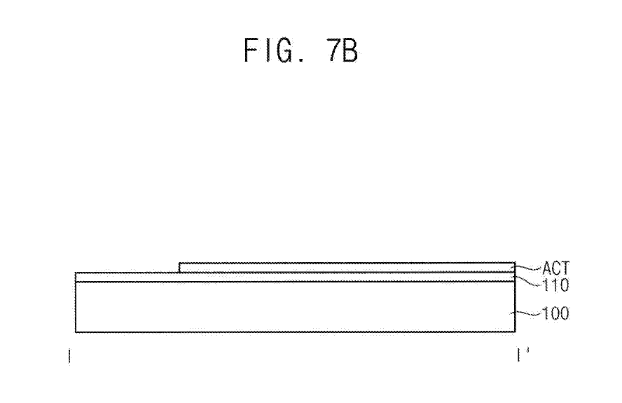

FIGS. 7A to 11B are plan views or cross-sectional views illustrating a method of manufacturing an organic light emitting display apparatus according to an example embodiment of the present invention.

Referring to FIGS. 7A and 7B, a buffer layer 110 may be formed on a base substrate 100. The base substrate 100 may include a transparent insulation substrate. For example, the base substrate 100 may include a glass substrate, a quartz substrate, a transparent resin substrate, etc. Examples of the transparent resin substrate for the base substrate 100 may include polyimide-based resin, acryl-based resin, polyacrylate-based resin, polycarbonate-based resin, polyether-based resin, sulfonic acid containing resin, polyethyleneterephthalate-based resin, etc.

The buffer layer 110 may be disposed (e.g., formed) on the base substrate 100. The buffer layer 110 may prevent or substantially prevent diffusion of metal atoms and/or impurities from the base substrate 100. Additionally, the buffer layer 110 may adjust a heat transfer rate of a successive crystallization process for an active pattern, to thereby obtain a uniform or substantially uniform active pattern. In the case that the base substrate 100 may have a relatively irregular surface, the buffer layer 110 may improve flatness of the surface of the base substrate 100. The buffer layer 110 may be formed using a silicon compound. For example, the buffer layer 110 may include at least one of silicon oxide (SiOx), silicon nitride (SiNx), silicon oxynitride (SiOxNy), silicon oxycarbide (SiOxCy), silicon carbon nitride (SiCxNy), etc., or a mixture thereof. The buffer layer 110 may have a single layer structure or a multi-layer structure. For example, the buffer layer 110 may have a single-layered structure including a silicon oxide film, a silicon nitride film, a silicon oxynitride film, a silicon oxycarbide film or a silicon carbon nitride film. Alternatively, the buffer layer 110 may have a multilayered structure including at least two of a silicon oxide film, a silicon nitride film, a silicon oxynitride film, a silicon oxycarbide film, a silicon carbon nitride film, etc.

The buffer layer 110 may be obtained (e.g., formed) on the base substrate 100 by a spin coating process, a chemical vapor deposition (CVD) process, a plasma enhanced chemical vapor deposition (PECVD) process, a high density plasma-chemical vapor deposition (HDP-CVD) process, a printing process, etc.

The active pattern ACT may be formed on the buffer layer 110. A semiconductor layer may be formed on the buffer layer 110, and a preliminary active layer may be formed on the buffer layer 110 by patterning the semiconductor layer. The crystallization process may be performed on the preliminary active layer to form the active pattern ACT on the buffer layer 110. Here, the semiconductor layer may be formed by a CVD process, a PECVD process, a low pressure chemical vapor deposition (LPCVD) process, a sputtering process, a printing process, etc. When the semiconductor layer includes amorphous silicon, the active pattern may include polysilicon. The crystallization process for forming the active pattern may include a laser irradiation process, a thermal treatment process, a thermal process utilizing a catalyst, etc. In some example embodiments, a dehydrogenation process may be performed on the semiconductor layer and/or the preliminary active layer after forming the semiconductor layer and/or the preliminary active layer on the buffer layer 110. The dehydrogenation process may reduce the hydrogen concentration of the semiconductor layer and/or the preliminary active layer, so that the active pattern may have improved electrical characteristics.

Referring to FIGS. 8A and FIG. 8B, a first insulation layer 120 may be formed on the buffer layer 110 on which the active pattern ACT is formed. The first insulation layer 120 may be disposed (e.g., formed) on the buffer layer 110 to cover the active pattern ACT. The first insulation layer 120 may include a silicon compound, metal oxide, etc. For example, the first insulation layer 120 may include at least one of silicon oxide (SiOx), silicon nitride (SiNx), silicon oxynitride (SiOxNy), aluminum oxide (AlOx), tantalum oxide (TaOx), hafnium oxide (HfOx), zirconium oxide (ZrOx), titanium oxide (TiOx), etc., or a combination thereof. In addition, the first insulation layer 120 may have a single layer structure or a multi-layer structure including the silicon oxide and/or the silicon nitride. In some embodiments, the first insulation layer 120 may be formed (e.g., uniformly or substantially uniformly formed) on the buffer layer 110 along a profile of the active pattern ACT. Here, the first insulation layer 120 may have a small or substantially small thickness, such that a stepped portion may be formed at a portion of the first insulation layer 120 that is adjacent to an edge of the active pattern ACT. In some example embodiments, the first insulation layer 120 may have a relatively large thickness to sufficiently cover the active pattern ACT, so that the first insulation layer 120 may have a level or substantially level surface.

The first insulation layer 120 may be formed by a CVD process, a spin coating process, a PECVD process, a sputtering process, a vacuum evaporation process, an HDP-CVD process, a printing process, etc.

A first gate pattern GP1 may be formed on the first insulation layer 120. The first gate pattern GP1 may include a metal, an alloy, a conductive metal oxide, a transparent conductive material, etc. For example, the first gate pattern GP1 may include aluminum (Al), alloy containing aluminum, aluminum nitride (AlNx), silver (Ag), alloy containing silver, tungsten (W), tungsten nitride (WNx), copper (Cu), alloy containing copper, nickel (Ni), alloy containing nickel, chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), indium tin oxide (ITO), tin oxide (SnOx), indium oxide (InOx), gallium oxide (GaOx), indium zinc oxide (IZO), etc., or a combination thereof. In some embodiments, the first gate pattern GP1 may have a single layer structure or a multi-layer structure, which may include a metal film, an alloy film, a metal nitride film, a conductive metal oxide film, and/or a transparent conductive film.

A first conductive layer may be formed on the first insulation layer 120, and the first conductive layer may be partially etched by a photolithography process or an etching process using an etching mask. Thus, the first gate pattern GP1 may be provided (e.g., formed) on the first insulation layer 120. The first conductive layer may be formed by a printing process, a sputtering process, a CVD process, a pulsed laser deposition (PLD) process, a vacuum evaporation process, an atomic layer deposition (ALD) process, etc.

The first gate pattern GP1 may include a first row line 121, a second row line 122, a third row line 123, a fourth row line 124, and a first storage electrode 125 of a storage capacitor. Gate electrodes of first to seventh transistors (see FIG. 2) may be formed where the first gate pattern GP1 overlaps the active pattern ACT.

After forming the first gate pattern GP1, a portion of the active pattern ACT which is not overlapped by the first gate pattern GP1 may be doped by an impurity, such that the doped portion of the active pattern ACT may have a higher electrical conductivity than other portions (or regions) of the active pattern ACT. The doped portion of the active pattern ACT may form source and/or drain electrodes of the first to seventh transistors.

Referring to FIGS. 9A and 9B, the second insulation layer 130 may be formed on the first insulation layer 120 on which the gate pattern GP1 is formed.

The second insulation layer 130 may be formed (e.g., uniformly or substantially uniformly formed) on the first insulation layer 120 along a profile of the first gate pattern GP1. Here, the second insulation layer 130 may have a small or substantially small thickness, such that a stepped portion may be formed at a portion of the second insulation layer 130 adjacent to an edge of the first gate pattern GP1. The second insulation layer 130 may include a silicon compound, etc. For example, the second insulation layer 130 may include at least one of silicon oxide (SiOx), silicon nitride (SiNx), silicon oxynitride (SiOxNy), silicon oxycarbide (SiOxCy), silicon carbon nitride (SiCxNy), etc., or a mixture thereof. The second insulation layer 130 may be formed by a spin coating process, a CVD process, a PECVD process, a HDP-CVD process, etc.

The second gate pattern GP2 may be formed on the second insulation layer 130.

The second gate pattern GP2 may include a metal, an alloy, a conductive metal oxide, a transparent conductive material, etc. For example, the second gate pattern GP2 may include at least one of aluminum (Al), alloy containing aluminum, aluminum nitride (AlNx), silver (Ag), alloy containing silver, tungsten (W), tungsten nitride (WNx), copper (Cu), alloy containing copper, nickel (Ni), alloy containing nickel, chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), indium tin oxide (ITO), tin oxide (SnOx), indium oxide (InOx), gallium oxide (GaOx), indium zinc oxide (IZO), etc., or a combination thereof. In some embodiments, the second gate pattern GP2 may have a single layer structure or a multi-layer structure, which may include a metal film, an alloy film, a metal nitride film, a conductive metal oxide film, and/or a transparent conductive film.

A second conductive layer may be formed on the second insulation layer 130, and the second conductive layer may be partially etched by a photolithography process or an etching process using an etching mask. Thus, the second gate pattern GP2 may be provided (e.g., formed) on the second insulation layer 130. The second conductive layer may be formed by a printing process, a sputtering process, a CVD process, a PLD process, a vacuum evaporation process, an ALD process, etc.

The second gate pattern GP2 may include a first overlapping line 131, a second overlapping line 132, a third overlapping line 133, and a storage line 134 including a second storage electrode of the storage capacitor. The first overlapping line 131 may overlap the first row line 121. The second overlapping line 132 may overlap the second row line 122. The third overlapping line 133 may overlap the fourth row line 124.

Referring to FIGS. 10A and 10B, a third insulation layer 140 may be formed on the second insulation layer 130 on which the gate pattern GP2 is formed.

The third insulation layer 140 may include a silicon compound, etc. For example, the third insulation layer 140 may include at least one of silicon oxide (SiOx), silicon nitride (SiNx), silicon oxynitride (SiOxNy), silicon oxycarbide (SiOxCy), silicon carbon nitride (SiCxNy), etc., or a mixture thereof. The third insulation layer 140 may be formed by a spin coating process, a CVD process, a PECVD process, a HDP-CVD process, etc.

A plurality of contact holes that expose a portion of the active pattern ACT, a portion of the first gate pattern GP1, and/or a portion of the second gate pattern GP2, are formed through the third insulation layer 140.

A data pattern DP may be formed on the third insulation layer 140.

In some example embodiments, the data pattern DP may include metal, alloy, conductive metal oxide, a transparent conductive material, etc. For example, the data pattern DP may include at least one of aluminum (Al), alloy containing aluminum, aluminum nitride (AlNx), silver (Ag), alloy containing silver, tungsten (W), tungsten nitride (WNx), copper (Cu), alloy containing copper, nickel (Ni), alloy containing nickel, chrome (Cr), chrome nitride (CrNx), molybdenum (Mo), alloy containing molybdenum, titanium (Ti), titanium nitride (TiNx), platinum (Pt), tantalum (Ta), tantalum nitride (TaNx), neodymium (Nd), scandium (Sc), strontium ruthenium oxide (SRO), zinc oxide (ZnOx), indium tin oxide (ITO), tin oxide (SnOx), indium oxide (InOx), gallium oxide (GaOx), indium zinc oxide (IZO), etc., or a combination thereof. In some example embodiments, the data pattern DP may have a single layer structure or a multi-layer structure, which may include a metal film, an alloy film, a metal nitride film, a conductive metal oxide film, and/or a transparent conductive film.

A third conductive layer may be formed on the third insulation layer 140, and the third conductive layer may be partially etched by a photolithography process or an etching process using an etching mask. Hence, the data pattern DP may be provided (e.g., formed) on the third insulation layer 140. The third conductive layer may be formed by a printing process, a sputtering process, a CVD process, a PLD process, a vacuum evaporation process, an ALD process, etc.

The data pattern DP may include an initialization voltage line 141, an emission control line 142, a power voltage line 143, a first data line 144a, a second data line 144b, a third data line 144c, a fourth data line 144d, a first gate line 145, a second gate line 146, a first connecting electrode 147, and a second connecting electrode 148.

The initialization voltage line 141 may extend in the second direction D2. The initialization voltage line 141 may be electrically connected to the active pattern ACT through a contact hole.

The emission control line 142 may be located adjacent to the initialization voltage line 141, and may extend in the second direction D2. The emission control line 142 may be electrically connected to the third row line 123 (see FIG. 8A), which extends in the first direction D1, through a contact hole.

The power voltage line 143 may be spaced from the emission control line 142 along the first direction D1, and may extend in the second direction D2. The power voltage line 143 may be electrically connected to a storage line 134 through a contact hole. In addition, the power voltage line 143 may be electrically connected to the active pattern ACT through the contact hole.

The first data line 144a may be spaced from the power voltage line 143 along the first direction D1, and may extend in the second direction D2.

The second data line 144b may be adjacent to the first data line 144a, and may extend in the second direction D2. The second data line 144b may be electrically connected to the active pattern ACT through a contact hole.

The third data line 144c may be adjacent to the second data line 144b, and may] extend in the second direction D2. The third data line 144c may be electrically connected to the active pattern ACT through a contact hole.

The fourth data line 144d may be adjacent to the third data line 144c, and may extend in the second direction D2.

The first gate line 145 may be spaced from the power voltage line 143 along the first direction D1, and may extend in the second direction D2. The first gate line 145 may be electrically connected to the second row line 122 through a contact hole.

The second gate line 146 may be adjacent to the first gate line 145, and may extend in the second direction D2. The second gate line 146 may be electrically connected to the first row line and the fourth row line 121 and 124 through contact holes.

The first connecting electrode 147 may be electrically connected to the active pattern ACT through a contact hole.

The second connecting electrode 148 may be electrically connected to the active pattern ACT and the first storage electrode 125 of the storage capacitor through contact holes.

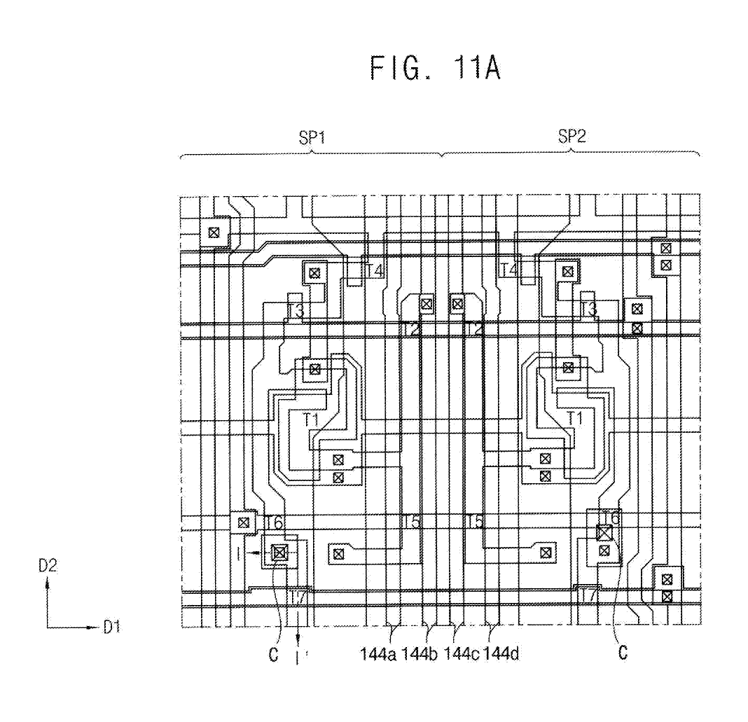

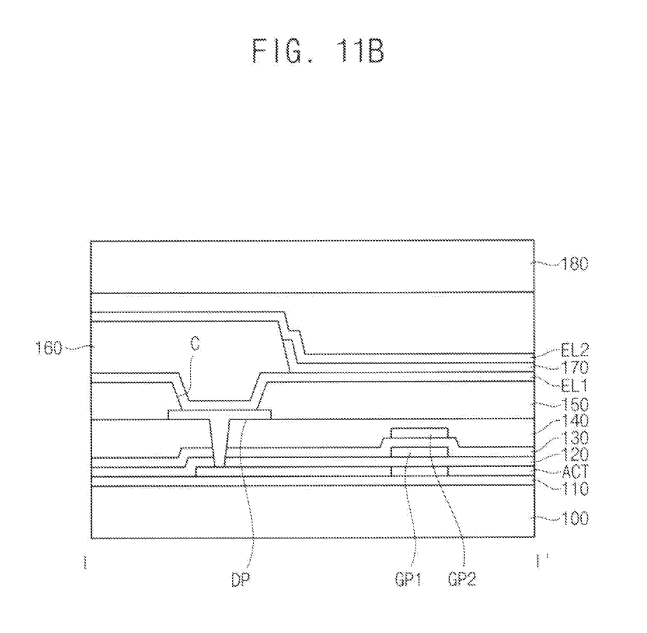

Referring to FIGS. 11A and 11 B, a fourth insulation layer 150 may be formed on the third insulation layer 140 on which the data pattern DP is formed.

The fourth insulation layer 150 may have a single-layered structure or a multi-layered structure including at least two insulation films. The fourth insulation layer 150 may be formed using an organic material. For example, the fourth insulation layer 150 may include at least one of photoresist, acryl-based resin, polyimide-based resin, polyamide-based resin, siloxane-based resin, etc., or a combination thereof.

Alternatively, the fourth insulation layer 150 may include an inorganic material. For example, the fourth insulation layer 150 may include at least one of silicon oxide, silicon nitride, silicon oxynitride, silicon oxycarbide, aluminum, magnesium, zinc, hafnium, zirconium, titanium, tantalum, aluminum oxide, titanium oxide, tantalum oxide, magnesium oxide, zinc oxide, hafnium oxide, zirconium oxide, titanium oxide, etc., or a mixture thereof.

The fourth insulation layer 150 may be obtained (e.g., formed) by a spin coating process, a printing process, a sputtering process, a CVD process, an ALD process, a PECVD process, an HDP-CVD process, and/or a vacuum evaporation process, according to the materials included in the fourth insulation layer 150.

A planarization process may be performed on the fourth insulation layer 150 to enhance the flatness of the fourth insulation layer 150. For example, the fourth insulation layer 150 may have a level or substantially level surface form a chemical mechanical polishing (CMP) process, an etch-back process, etc.

A via hole C that exposes the first connecting electrode 147 may be formed through the fourth insulation layer 150.

A first electrode ELI may be formed on the fourth insulation layer 150. A fourth conductive layer may be formed on the fourth insulation layer 150 to fill the via hole C. The first electrode ELI may be obtained (e.g., formed) by patterning the fourth conductive layer. Here, the fourth conductive layer may be formed by a printing process, a sputtering process, a CVD process, a PLD process, a vacuum evaporation process, an ALD process, etc.

The first electrode ELI may include a reflective material or a transmissive material according to the emission type of the display apparatus. For example, the first electrode ELI may include at least one of aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, etc., or a combination thereof. In some embodiments, the first electrode ELI may have a single layer structure or a multi-layer structure, which may include a metal film, an alloy film, a metal nitride film, a conductive metal oxide film, and/or a transparent conductive film.

A pixel defining layer 160 may be formed on the fourth insulation layer 150 on which the first electrode ELI is formed. The pixel defining layer 160 may include an organic material and/or an inorganic material. For example, the pixel defining layer 160 may be formed using photoresist, acryl-based resin, polyacryl-based resin, polyimide-based resin, a silicon compound, etc. The pixel defining layer 160 may be formed by a spin coating process, a spray process, a printing process, a CVD process, a PECVD process, an HDP-CVD process, etc.

In some example embodiments, the pixel defining layer 160 may be partially etched to form an opening that partially exposes the first electrode ELI . The opening of the pixel defining layer 160 may define a luminescent region and a non-luminescent region of the display apparatus. For example, a portion of the display apparatus having the opening of the pixel defining layer 160 may be the luminescent region of the display device, while the portion of the display apparatus adjacent to the opening of the pixel defining layer 160 may be the non-luminescent region of the display device.

The light emitting structure 170 may be located on the first electrode ELI that is exposed by the opening of the pixel defining layer 160. The light emitting structure 170 may extend on a sidewall of the opening of the pixel defining layer 160. The light emitting structure 170 may be formed by a laser induced thermal imaging process, a printing process, etc. The light emitting structure 170 may include at least one of an organic light emitting layer (EL), a hole injection layer (HIL), a hole transfer layer (HTL), an electron transfer layer (ETL), an electron injection layer (EIL), etc. In some embodiments, a plurality of organic light emitting layers may be formed using light emitting materials for generating different colors of light, such as a red color of light (R), a green color of light (G), and/or a blue color of light (B), according to the color of the pixels of the display device. In some example embodiments, the organic light emitting layer of the of the light emitting structure 170 may include a plurality of stacked light emitting materials for generating a red color of light, a green color of light, and a blue color of light, to thereby emitting a white color of light.

The second electrode EL2 may be formed on the light emitting structure 170 and the pixel defining layer 160. The second electrode EL2 may include a transmissive material or a reflective material according to the emission type of the display device. For example, the second electrode EL2 may include at least one of aluminum, alloy containing aluminum, aluminum nitride, silver, alloy containing silver, tungsten, tungsten nitride, copper, alloy containing copper, nickel, alloy containing nickel, chrome, chrome nitride, molybdenum, alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, indium zinc oxide, etc., or a combination thereof. In some example embodiments, the second electrode EL2 may have a single layer structure or a multi-layer structure, which may include a metal film, an alloy film, a metal nitride film, a conductive metal oxide film, and/or a transparent conductive film.

The sealing substrate 180 may be formed on the second electrode EL2. The sealing substrate 180 may include a transparent material, and may be configured to prevent or substantially prevent ambient air and/or moisture from permeating into the transparent organic light emitting display apparatus. The sealing substrate 180 may be connected to the base substrate 100 to seal a space between the base substrate 100 and the sealing substrate 180 by a sealing agent. A desiccant or a filler may be filled in the space.

However, the present invention is not limited thereto, and in some embodiments, a sealing film (e.g., a thin sealing film), instead of the sealing substrate 180, may be formed on the second electrode EL2 to protect the second electrode EL2 and the light emitting structure 170 from ambient air and/or moisture. The sealing film has a structure in which a layer formed of an inorganic material, such as silicon oxide and/or silicon nitride, and a layer such as epoxy and/or polyimide are alternately stacked. However the present invention is not limited thereto, and the structure of the sealing film may be any suitable sealing structure in the form of a transparent thin film.

According to one or more example embodiments of the present invention, coupling capacitance between data lines and gate lines, which extend in a same direction, may be reduced, so that display quality of an organic light emitting display apparatus may be improved.

The electronic or electric devices (e.g., the gate driver, the data driver, etc.) and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

The foregoing is illustrative of the present invention and is not to be construed as limiting thereof. Although a few example embodiments of the present invention have been described, those skilled in the art will readily appreciate that various modifications may be possible to the example embodiments without departing from the spirit and scope of the present invention. Accordingly, all such modifications are intended to be included within the scope of the present invention as defined in the claims, and their equivalents. In the claims, means-plus-function clauses, if any, are intended to cover the structures described herein as performing the recited function, and not only structural equivalents but also equivalent structures. Therefore, it is to be understood that the foregoing is illustrative of aspects and features of the present invention, and is not to be construed as limited to the specific example embodiments described, and that modifications to the disclosed example embodiments, as well as other example embodiments, are intended to be included within the scope of the appended claims, and their equivalents. The present invention is defined by the following claims, with equivalents of the claims to be included therein.

What is claimed is:

1. A display apparatus comprising:
a first gate line extending in a second direction crossing a first direction;
a row line extending in the first direction and electrically connected to the first gate line;
a first data line spaced from the first gate line along the first direction and extending in the second direction;
a second data line adjacent to the first data line and extending in the second direction;
a first sub-pixel electrically connected to the first data line; and
a second sub-pixel electrically connected to the second data line.

2. The display apparatus of claim 1, further comprising:
a data driver configured to provide data signals to the first and second data lines; and
a gate driver configured to provide a gate signal to the first gate line,
wherein the data driver and the gate driver are located at a same side of the display apparatus, or located at opposite sides of the display apparatus, respectively.

3. The display apparatus of claim 2, wherein the first sub-pixel comprises a first driving transistor, and the second sub-pixel comprises a second driving transistor, and
wherein the first data line and the second data line are located between the first driving transistor and the second driving transistor.

4. The display apparatus of claim 3, further comprising a power voltage line extending in the second direction and configured to provide a first power voltage to the first and second sub-pixels,
wherein the power voltage line is located between the first gate line and the first and second data lines.

5. The display apparatus of claim 4, wherein the power voltage line is connected to a conductive line extending in the first direction to form a mesh structure.

6. The display apparatus of claim 4, further comprising an initialization voltage line spaced from the power voltage line along the first direction and extending in the second direction.

7. The display apparatus of claim 6, wherein the initialization voltage line is connected to a conductive line extending in the first direction to form a mesh structure.

8. The display apparatus of claim 2, wherein the data driver comprises a demultiplexer configured to provide the data signals generated from a first data signal to the first and second data lines in response to a first control signal.

9. The display apparatus of claim 2, further comprises:
a second gate line adjacent to the first gate line and extending in the second direction;
a third data line adjacent to the first data line and extending in the second direction;
a fourth data line adjacent to the second data line and extending in the second direction;
a third sub-pixel electrically connected to the third data line; and
a fourth sub-pixel electrically connected to the fourth data line.

10. The display apparatus of claim 9, wherein the first to fourth data lines are formed in a same layer and comprise a same material.

11. The display apparatus of claim 9, wherein each of the first and second sub-pixels comprises a first electrode, a second electrode facing the first electrode, and an organic light emitting layer between the first electrode and the second electrode.

12. The display apparatus of claim 11, further comprising fifth to eighth data lines that are adjacent to each other and extend in the second direction,
wherein the data driver further comprises a demultiplexer configured to provide the data signals to the first to eighth data lines, and
the demultiplexer is configured to provide the data signals to the first to fourth data lines in response to a first control signal, and to provide the data signals to the fifth to eighth data lines in response to a second control signal.

13. The display apparatus of claim 1, wherein the first and second data lines are located between the first sub-pixel and the second sub-pixel.

14. The display apparatus of claim 1, further comprising an overlapping line extending in the first direction, electrically connected to the row line, and overlapping the row line.

15. A display apparatus comprising:
first and second data lines electrically connected to first and second switching elements, respectively, and configured to transmit data signals in response to a first control signal;
third and fourth data lines electrically connected to third and fourth switching elements, respectively, and configured to transmit data signals in response to a second control signal;
a first transmit line electrically connected to the first switching element and the third switching element; and
a second transmit line electrically connected to the second switching element and the fourth switching element,
wherein the first data line and the second data line are adjacent to each other, and the third data line and the fourth data line are adjacent to each other.

16. The display apparatus of claim 15, further comprising a first gate line spaced from the first and second data lines and extending in parallel with the first and second data lines.

17. The display apparatus of claim 16, further comprising:
a data driver configured to provide the data signals to the first and second data lines; and
a gate driver configured to provide a gate signal to the first gate line,
wherein the data driver and the gate driver are located at a same side of the display apparatus, or located at opposite sides of the display apparatus.

18. The display apparatus of claim 17, further comprising a voltage line between the first gate line and the first and second data lines and extending in parallel with the first and second data lines.

19. The display apparatus of claim 18, wherein the voltage line comprises a power voltage line or an initialization voltage line.

20. A display apparatus comprising:
a plurality of pixels;
a data driver adjacent to an area where the pixels are located and configured to provide data signals to the pixels;
a gate driver adjacent to the data driver and configured to provide gate signals to the pixels;
first and second data lines adjacent to each other and extending in parallel with each other;
a gate line spaced from the first and second data lines and extending in parallel with the first and second data lines; and
a voltage line between the gate line and the first and second data lines.
